(19) United States
(12) Patent Application Publication
(10) Pub. No.: US 2002/0068409 A1
(43) Pub. Date: Jun. 6, 2002

(54) METHOD OF REDUCING JUNCTION CAPACITANCE

(76) Inventors: JIH-WEN CHOU, HSINCHU (TW); YAO-CHIN CHENG, CHI-LUNG CITY (TW); F. S. LIAO, HSIEN (TW)

Correspondence Address: J C Patents Inc, 4 Venture, Suite 250, Irvine, CA, 92618, US

(21) Appl. No.: 09/243,188

(22) Filed: Feb. 2, 1999

(51) Int. Cl. H01L 21/8238; H01L 21/336

(52) U.S. Cl. 438/301; 438/199; 438/291; 438/289

(57) ABSTRACT

A method of reducing junction capacitance. In a doped substrate or well, a super steep counter-doped implantation is performed, so as to form a super steep counter-doped region beneath the source/drain region in the substrate. As a consequence, the region near the source/drain region has a reduced doping concentration, and the junction capacitance of the source/drain region is reduced.

### BACKGROUND OF THE INVENTION

1. Field of the Invention

The invention relates to a method of reducing junction capacitance, and more particularly, to a method of fabricating a metal-oxide semiconductor (MOS), or a complementary MOS (CMOS).

2. Description of the Related Art

In the sub-micron or deep sub-micron semiconductor fabrication technique, according to function and characteristic requirements, the doping concentration of a doped substrate or a doped well is increased. Therefore, while forming a region having a contrary conductive type in the doped substrate or the doped well, an abrupt junction is resulted. It is known that the junction capacitance is determined by the substrate doping concentration and the junction area. The capacitance is easily estimated using Cⱼ=εA/W, where W is the junction depletion width, and ε is the dielectric permittivity. Taking a silicon substrate as an example, ε=1.05×10⁻¹² F/cm. Therefore, a large junction capacitance is resulted since the depletion length W of the junction is small due to the abrupt junction profile. The large value of junction capacitance causes a long propagation delay time, so that the device characteristics are seriously degraded.

### SUMMARY OF THE INVENTION

Accordingly, the invention provides a method of reducing junction capacitance, so as to enhance the device performance. A substrate is provided. A gate oxide layer and a gate on the gate oxide layer are formed. A source/drain region is formed in the substrate. Using ion implantation, a super steep counter-doped region is formed near the source/drain region under the gate and the source/drain region. While a P-type substrate or a P-well is used, N-type ions such as arsenic (As) or antimony (Sb) ions are used and implanted. In contrast, while an N-type substrate or an N-well is used, P-type ions such as indium ions are implanted into the substrate. Apart from the formation of a MOS, the invention can be applied in many kinds of junctions and devices in order to reduce junction capacitance.

In addition, the invention also provides a method for fabrication a MOS. Apart from the gate on the substrate and the source/drain region in the substrate, a spacer is formed around the gate, and a super steep counter-doped region near the source/drain region with a same depth of the source/drain region is formed.

From the above method and structure, a continuous super steep counter-doped region is formed under both the gate and the source/drain region in the substrate. The super steep counter-doped region is doped at a depth about the same of the source/drain region. The junction profile is then smoothed, and the junction capacitance is thus effectively reduced.

It is to be understood that both the foregoing general description and the following detailed description are exemplary and explanatory only and are not restrictive of the invention, as claimed.

### BRIEF DESCRIPTION OF THE DRAWINGS

FIG. 1A to FIG. 1B shows a method of reducing the junction capacitance according to the invention; and

FIG. 2 shows a comparison between a doped substrate with and without being super steep counter-doped implanted.

### DESCRIPTION OF THE PREFERRED EMBODIMENTS

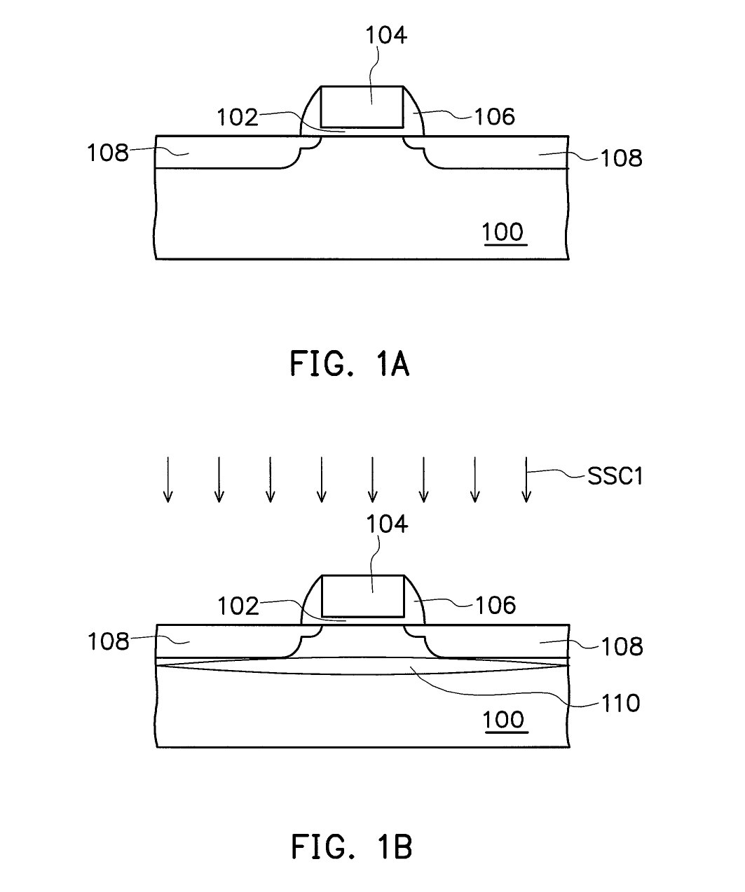

FIG. 1A to FIG. 1B shows a method of reducing a junction capacitance according to the invention. A MOS device is taken as an example in this embodiment. It is appreciated that the application of the technique introduced here is not restricted in the fabrication of a MOS device. Other junction structures or devices such as a CMOS may also adapts this invention in order to effectively reduce the junction capacitance.

In FIG. 1A, a substrate 100 is provided. A gate oxide layer 102 is formed on the substrate 100. A gate 104 is formed on the gate oxide layer 102. It is very often that a spacer 106 is formed around a side wall of the gate 104. In the substrate 100, a source/drain region 108 is formed. To prevent a short channel effect, the source/drain region 108 typically comprises a lightly doped drain region (LDD) under or near the area under the gate 104. In the invention, the substrate 100 comprises a doped substrate or a doped well.

Referring to FIG. 1B, while an N-type substrate or an N-well is in use as the substrate 100, a P-type source/drain region 108 is formed. Beneath both the gate 104 and the source/drain region 108, using super steep counter-doped implantation, P-type ions, such as indium ions are implanted with a depth roughly deeper than the depth of the source/drain region 108. Thus, a super steep counter doped region 110 is formed, so that the abrupt junction of the source/drain region 108 is smoothed. The P-type ions are doped with an implanting energy larger than about 200 KeV. However, the implanting energy is determined on the specific depth of the source/drain region 108, or the position to form the super steep counter doped region 110.

In contrast, while a P-type substrate or a P-well is in use as the substrate 100, an N-type source/drain region 108 is formed. Beneath both the gate 104 and the source/drain region 108, using super steep counter-doped implantation, N-type ions, such as arsenic or antimony ions are implanted with a depth roughly deeper than the depth of the source/drain region 108. Thus, a continuous super steep counter doped region 110 is formed, so that the abrupt junction of the source/drain region 108 is smoothed. The P-type ions are doped with an implanting energy larger than about 200 KeV. Again, the implanting energy is determined on the specific depth of the source/drain region 108, or the position to form the super steep counter doped region 110.

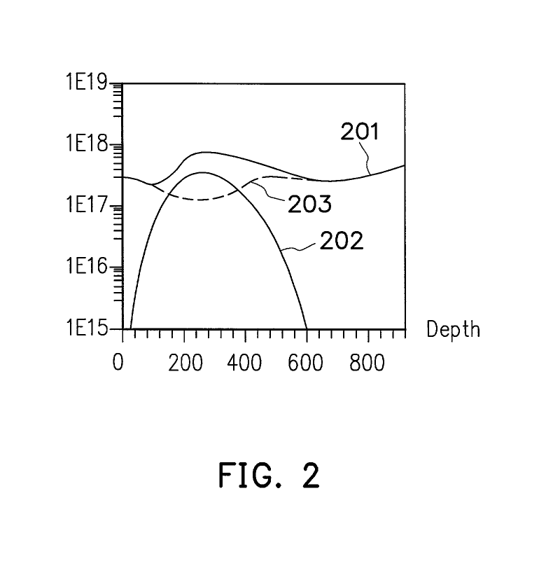

Referring to Table 1 and FIG. 2, an NMOS is taken as an example for a further description of the invention. The NMOS device comprises a P-type substrate and a super steep counter-doped region implanted with arsenic ions in the substrate. Device characteristics and junction capacitance of the NMOS with and without the super steep counter-doped region are listed in Table 1. As shown in the table, the device characteristics are not altered with the formation of the super steep counter-doped region. However, the junction capacitance of the source/drain region is effectively reduced. For example, in this embodiment, the junction capacitance is reduced to about 65% of the original value.

TABLE 1

| | | | | Drain induced | |
|---|---|---|---|---|---|
| | Threshold | Saturation | Cut-off | barrier | Junction |
| | Voltage | current | current | lowering cur- | Capacitance |
| Device | (Vt) | (Idsat) | (Ioff) | rent (I_{DBL}) | (Cj) |
| NMOS | 0.51 | 626 | 2.0 | 30 | 1.09 |
| with | | | | | |
| SSCI | | | | | |
| NMOS | 0.50 | 640 | 3.0 | 34 | 0.70 |
| without | | | | | |
| SSCI | | | | | |

FIG. 2 shows a diagram of doping concentration for different regions. Curve 201 represents the doping concentration in the P-well without the formation of the super steep counter-doped region, curve 202 represents the doping concentration of the super steep counter-doped region, while curve 203 represents net concentration distribution of the P-well comprising the super steep counter-doped region.

From the data in Table 1 and the doping concentration distribution shown in FIG. 2, the capacitance is effectively reduced without affecting the device characteristics.

Other embodiment of the invention will appear to those skilled in the art from consideration of the specification and practice of the invention disclosed herein. It is intended that the specification and examples to be considered as exemplary only, with a true scope and spirit of the invention being indicated by the following claims.

What is claimed is:

1. A method of reducing junction capacitance, comprising:
providing a first conductive type substrate;
forming a gate on the first conductive type substrate;
forming a second conductive type source/drain region; and
performing an ion implantation with a second type ion into a position at a substantially same depth of the source/drain region in the substrate.

2. The method according to claim 1, wherein the first conductive type comprises P-type, and the second conductive type comprises N-type.

3. The method according to claim 2, wherein the first conductive type substrate comprises a substrate doped with boron ions.

4. The method according to claim 2, wherein the first conductive type comprises a P-well.

5. The method according to claim 1, wherein the second conductive type ion comprises arsenic ion.

6. The method according to claim 2, wherein the second conductive type ion comprises antimony ion.

7. The method according to claim 1, wherein the first conductive type comprises N-type and the second conductive type comprises P-type.

8. The method according to claim 7, wherein the first conductive type substrate comprises an N-well.

9. The method according to claim 7, wherein the second conductive type ion comprise indium ion.

10. The method according to claim 1, wherein the second conductive ion is implanted with an energy larger than about 200 KeV.

11. A method of reducing junction capacitance, comprising:
providing a first conductive type substrate, the first conductive type substrate comprising a second conductive type MOS; and
forming a continuous super steep counter-doped region under the second conductive type MOS.

12. The method according to claim 1, wherein the super steep counter-doped region comprises a second conductive type.

13. The method according to claim 11, wherein the MOS further comprises a gate on the substrate and a second conductive type source/drain region in the substrate.

14. The method according to claim 1, wherein the first conductive type comprises P-type, while the second conductive type comprises N-type.

15. The method according to claim 14, wherein the substrate comprises a P-well.

16. The method according to claim 11, wherein the first conductive type comprises N-type, while the second conductive type comprises P-type.

17. The method according to claim 16, wherein the substrate comprises an N-well.
